(19) United States
(12) Patent Application Publication
(10) Pub. No.: US 2024/0395899 A1
(43) Pub. Date: Nov. 28, 2024

(54) SEMICONDUCTOR STRUCTURE AND METHOD FOR FORMING THE SAME

(71) Applicant: Taiwan Semiconductor Manufacturing Company, Ltd., Hsinchu (TW)

(72) Inventors: Cherng-Rong HO, Hsinchu (TW); Min-Yann HSIEH, Kaohsiung City (TW); Jeng-Ya YEH, New Taipei City (TW)

(73) Assignee: Taiwan Semiconductor Manufacturing Company, Ltd., Hsinchu (TW)

(21) Appl. No.: 18/321,512

(22) Filed: May 22, 2023

(51) Int. Cl. H01L 29/66; H01L 21/8238; H01L 27/088; H01L 29/06; H01L 29/423; H01L 29/775; H01L 29/786

(52) U.S. Cl. CPC H01L 29/66545; H01L 21/823807; H01L 21/823871; H01L 27/088; H01L 29/0673; H01L 29/42392; H01L 29/66439; H01L 29/775; H01L 29/78696

(57) ABSTRACT

A method for forming a semiconductor structure is provided. The method includes forming a channel layer over a substrate, forming a source/drain feature adjoining the channel layer, and forming a gate stack over the channel layer. The gate stack includes a gate dielectric layer and a gate electrode layer nested within the gate dielectric layer. The method also includes recessing the gate dielectric layer to expose the gate electrode layer, forming a filling layer over the gate stack and the source/drain feature, and forming a contact plug through the filling layer and on the source/drain feature.

### BACKGROUND

The electronics industry is experiencing an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). One such multi-gate device that has been introduced is the gate-all around transistor (GAA). The GAA device gets its name from the gate structure, which can extend around the channel region and provide access to the channel on two or four sides. GAA devices are compatible with conventional complementary metal-oxide-semiconductor (CMOS) processes, and their structure allows them to be aggressively scaled-down while maintaining gate control and mitigating SCEs. In conventional processes, GAA devices provide a channel in a silicon nanowire. However, integration of fabrication of the GAA features around the nanowire can be challenging. For example, while current methods have been satisfactory in many respects, continued improvements are still needed.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a perspective view of a semiconductor structure, in accordance with some embodiments of the disclosure.

FIGS. 2A-1, 2B-1, 2C-1, 2D-1, 2E-1, 2F-1, 2G-1, 2H-1, 2I-1, 2J-1, 2K-1 and 2L-1 are cross-sectional views illustrating the formation of a semiconductor structure at various intermediate stages, in accordance with some embodiments of the disclosure.

FIGS. 2A-2, 2B-2, 2C-2, 2D-2, 2E-2, 2F-2, 2G-2, 2H-2, 2I-2, 2J-2, 2K-2 and 2L-2 are cross-sectional views illustrating the formation of a semiconductor structure at various intermediate stages, in accordance with some embodiments of the disclosure.

FIG. 3 is a modification of the semiconductor structure of FIG. 2L-1, in accordance with some embodiments of the disclosure.

FIG. 4 is a modification of the semiconductor structure of FIG. 2L-1, in accordance with some embodiments of the disclosure.

FIG. 5 is a modification of the semiconductor structure of FIG. 2L-1, in accordance with some embodiments of the disclosure.

FIG. 6 is a modification of the semiconductor structure of FIG. 2L-1, in accordance with some embodiments of the disclosure.

FIGS. 7-1 and 7-2 are a modification of the semiconductor structure of FIGS. 2L-1 and 2L-2, in accordance with some embodiments of the disclosure.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The nanostructure transistor (e.g., nanosheet transistor, nanowire transistor, multi-bridge channel, nano-ribbon FET, gate all around (GAA) transistor structures) described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments of a semiconductor structure and a method for forming the semiconductor structure are provided. The method includes recessing a gate dielectric of a gate stack to expose the top gate electrode layer of the gate stack, forming a filling layer over the top gate electrode layer and a source/drain feature, and forming a contact opening through the filling layer and to the source/drain feature. As a result, the critical dimension of the top portion of the gate stack may shrink, and the spacing between a contact plug and the final gate stack may thus increase. Therefore, the overlay window of the photolithography process for forming the contact opening may be relaxed, which may facilitate the scaling down of the gate-to-gate pitch.

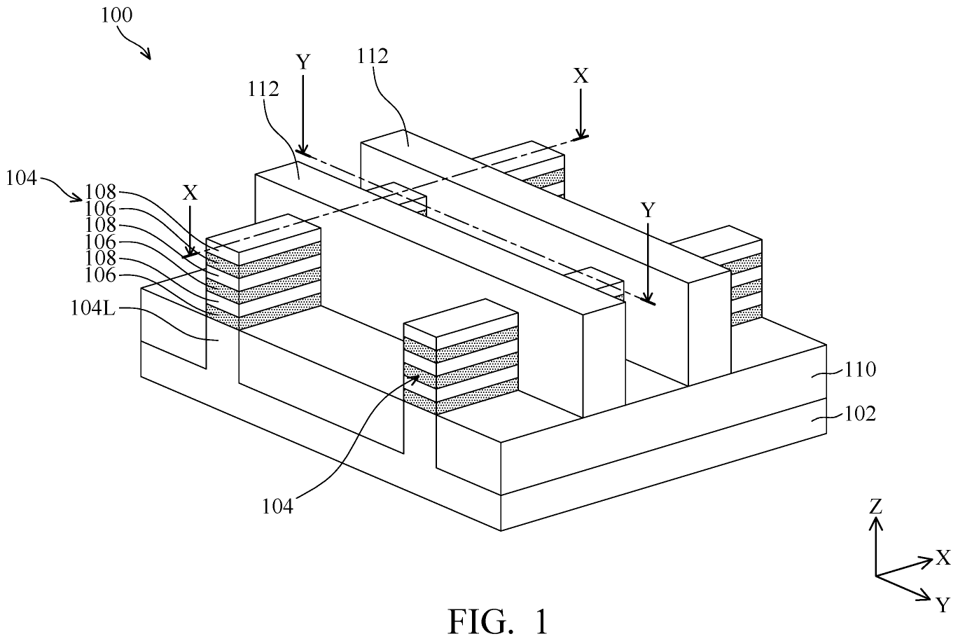

FIG. 1 is a perspective view of a semiconductor structure 100, in accordance with some embodiments. A semiconductor structure 100 is provided, as shown in FIG. 1, in accordance with some embodiments. The semiconductor structure 100 includes a substrate 102 and fin structures 104 and an isolation structure 110 over the substrate 102, in accordance with some embodiments.

For a better understanding of the semiconductor structure, X-Y-Z coordinate reference is provided in the figures of the present disclosure. The X-axis and the Y-axis are generally orientated along the lateral (or horizontal) directions that are parallel to the main surface of the substrate 102. The Y-axis is transverse (e.g., substantially perpendicular) to the X-axis. The Z-axis is generally oriented along the vertical direction that is perpendicular to the main surface of the substrate 102 (or the X-Y plane).

Each of the fin structures 104 includes a lower fin element 104L surrounded by the isolation structure 110 and an upper fin element formed from an epitaxial stack including alternating first semiconductor layers 106 and second semiconductor layer 108, in accordance with some embodiments. The second semiconductor layers 108 will form nanostructures (e.g., nanowires or nanosheets) and serve as the channel for the resulting semiconductor devices, in accordance with some embodiments.

The fin structures 104 extend in the X direction, in accordance with some embodiments. That is, the fin structures 104 have longitudinal axes parallel to the X direction, in accordance with some embodiments. The X direction may also be referred to as the channel-extending direction. The current of the resulting semiconductor device (i.e., nanostructure transistor) flows in the X direction through the channel. Each of the fin structures 104 is defined as several channel regions and several source/drain regions, where the channel regions and the source/drain regions are alternately arranged, in accordance with some embodiments. In this disclosure, a source/drain refers to a source and/or a drain. It is noted that in the present disclosure, a source and a drain are interchangeably used and the structures thereof are substantially the same.

Gate structures 112 are formed with longitudinal axes parallel to the Y direction and extending across and/or surrounding the channel regions of the fin structures 104, in accordance with some embodiments. The source/drain regions of the fin structures 104 are exposed from the gate structures 112, in accordance with some embodiments. The Y direction may also be referred to as a gate-extending direction, in accordance with some embodiments.

FIG. 1 further illustrates a reference cross-section that is used in later figures. Cross-section X-X is in a plan parallel to the longitudinal axis of the active region 104 (i.e., X direction) and through the active region 104, in accordance with some embodiments. Cross-section Y-Y is in a plan parallel to the longitudinal axis of the gate structure (i.e., Y direction) and across the source/drain regions of the active regions 104, in accordance with some embodiments.

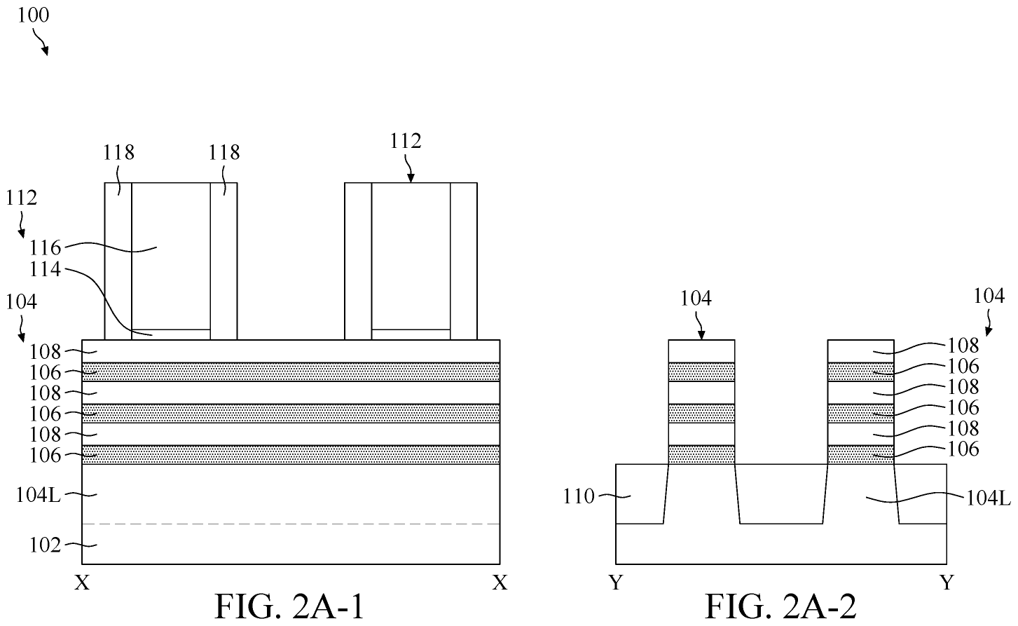

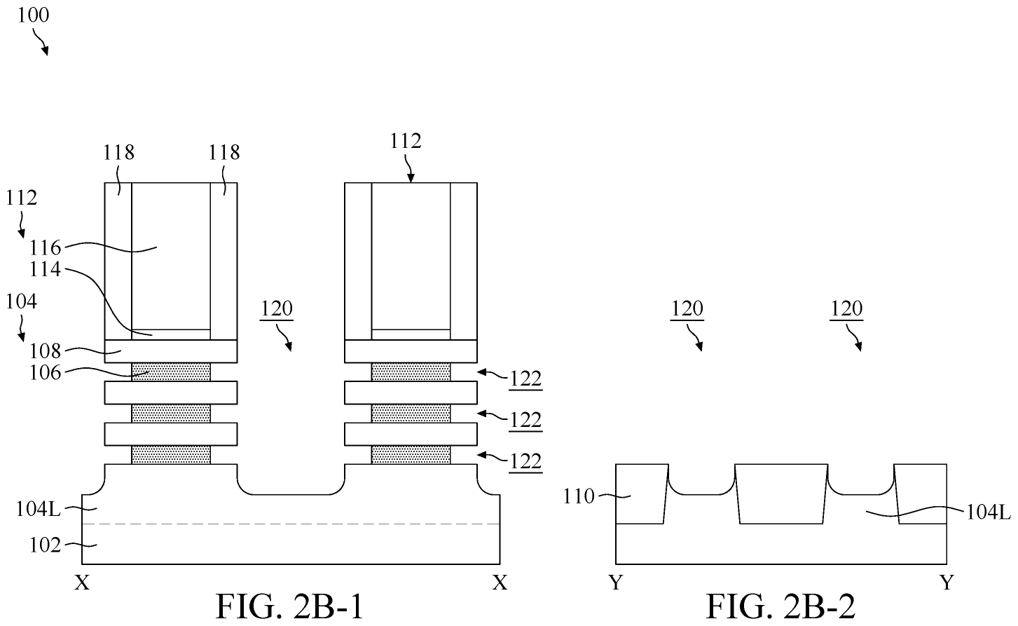

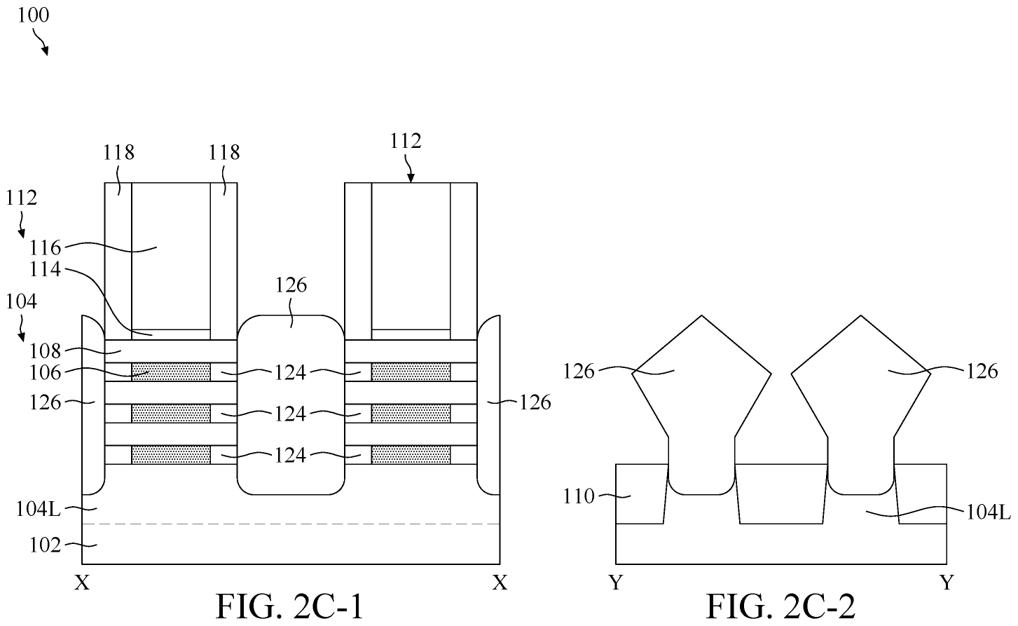

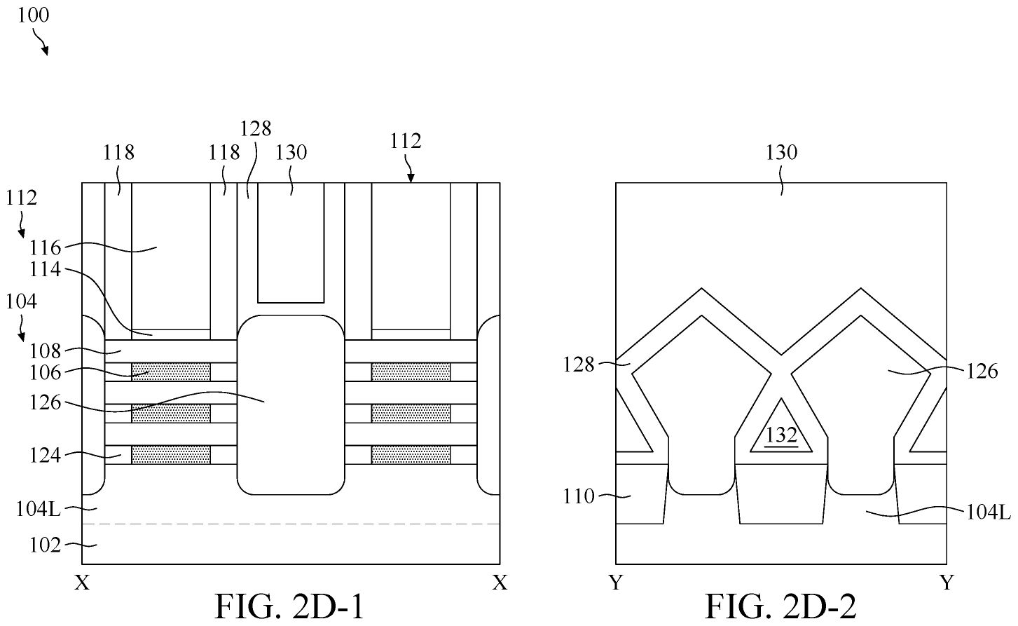

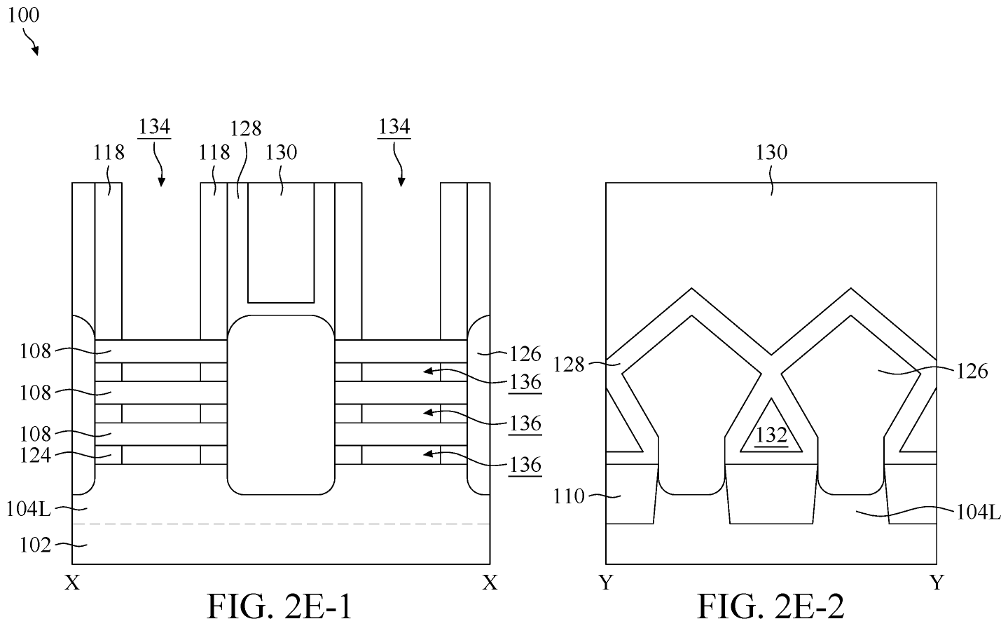

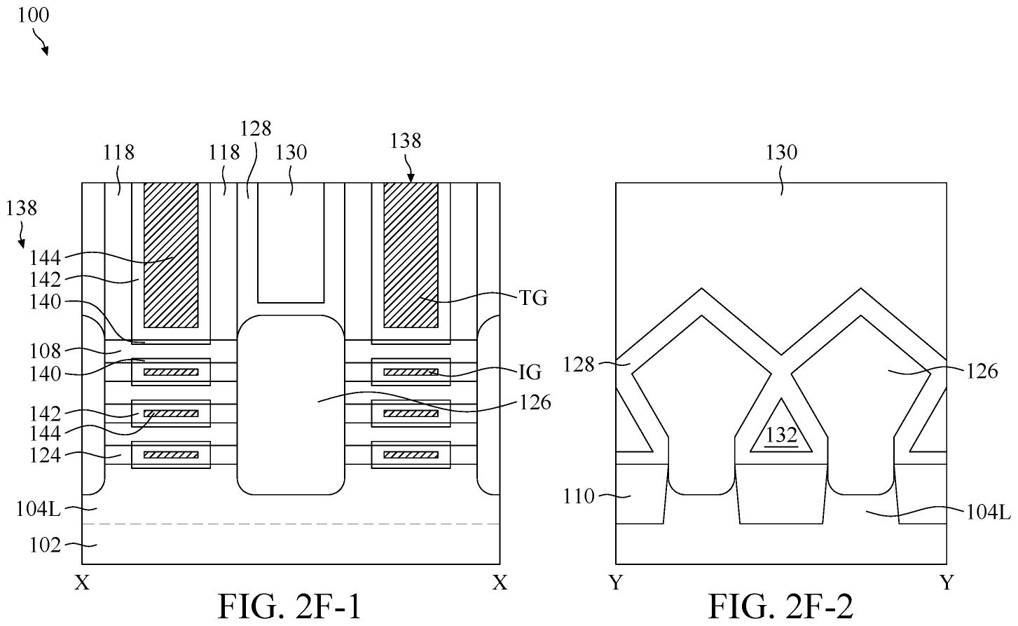

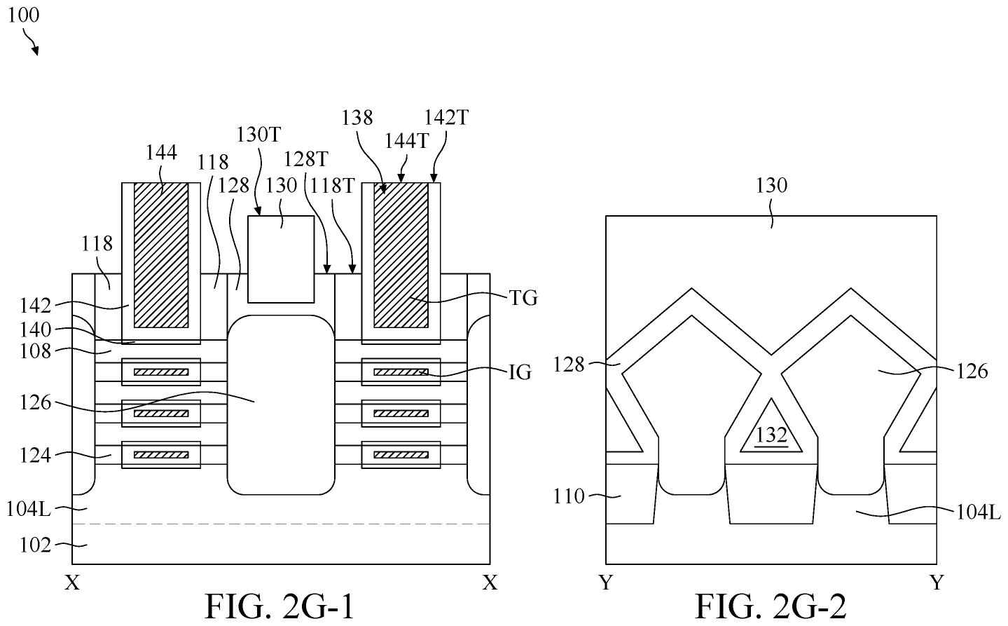

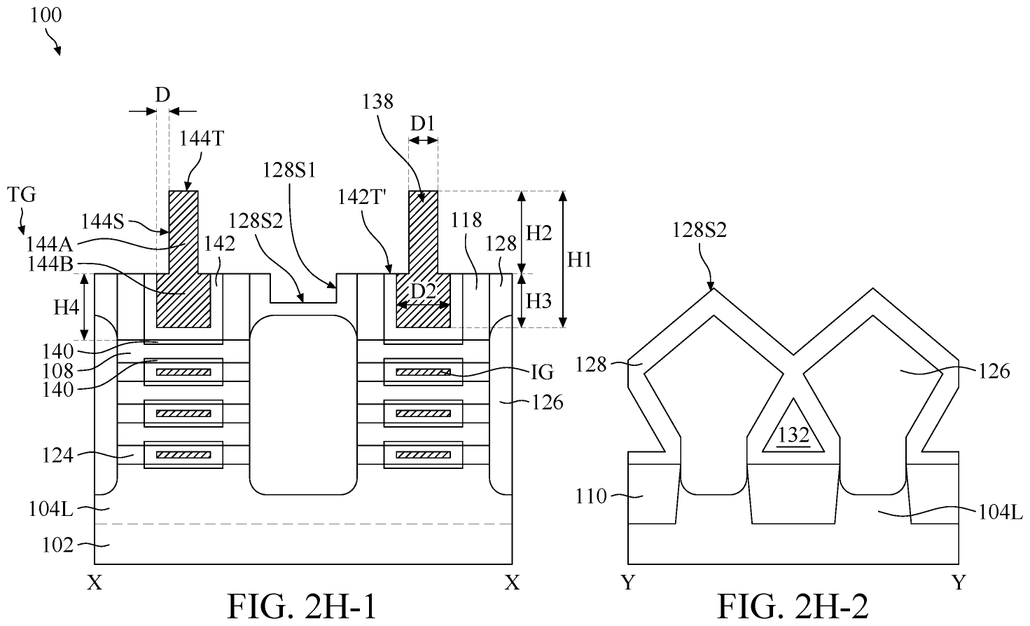

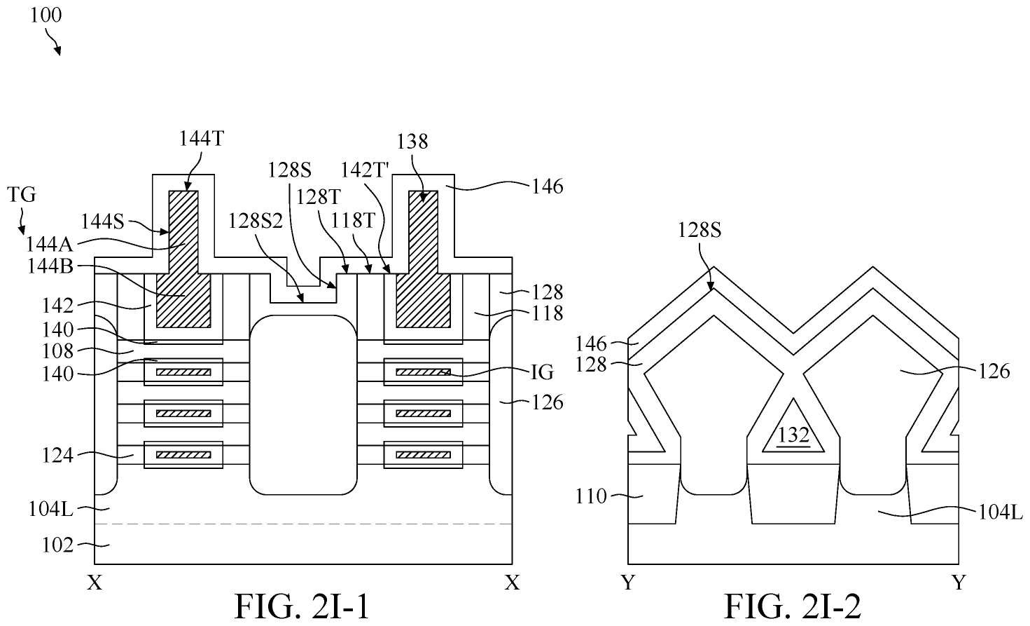

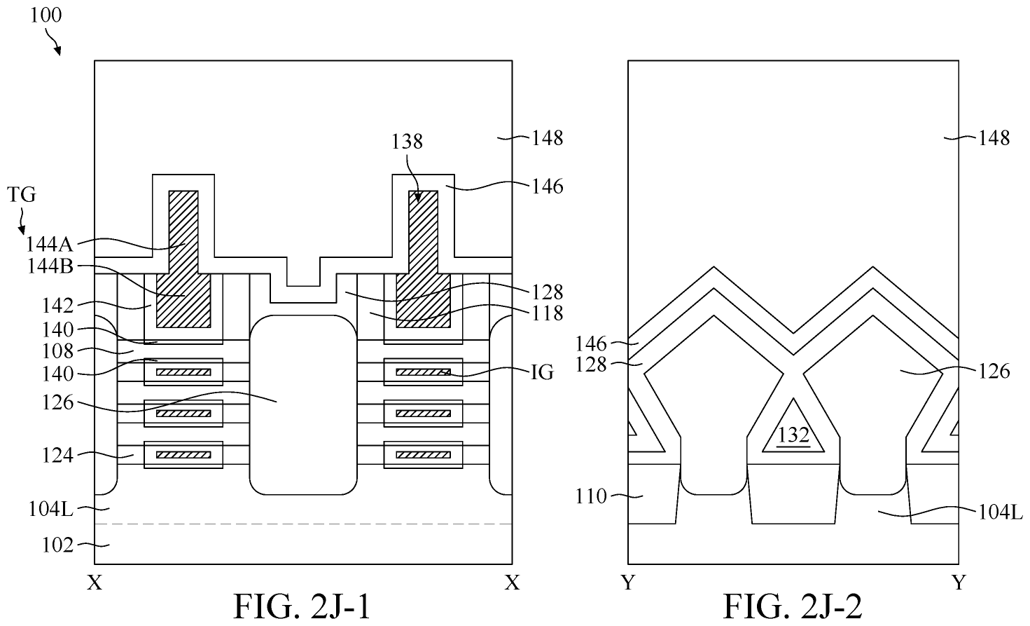

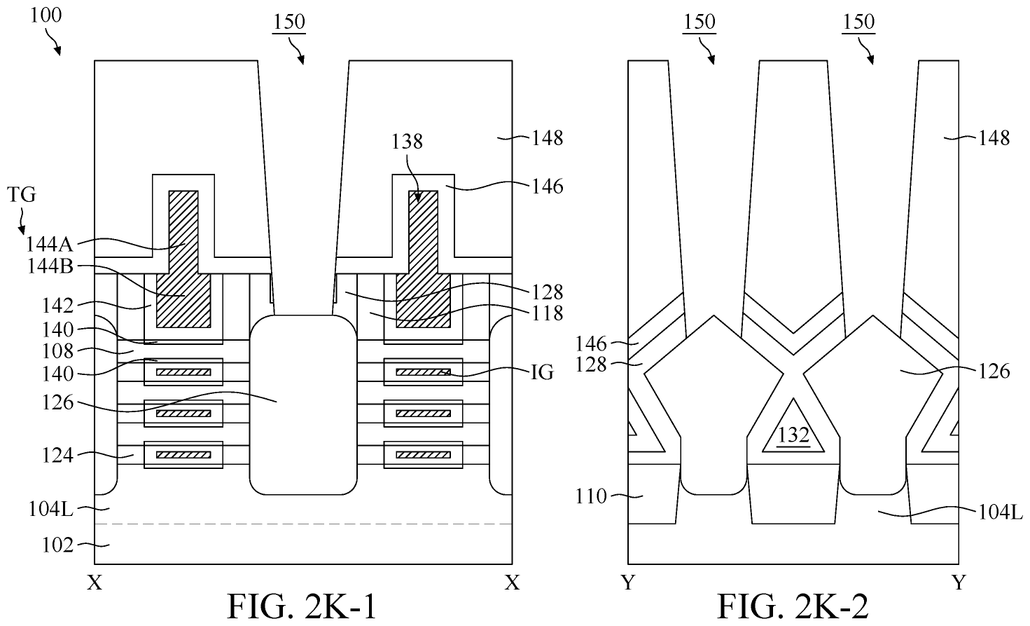

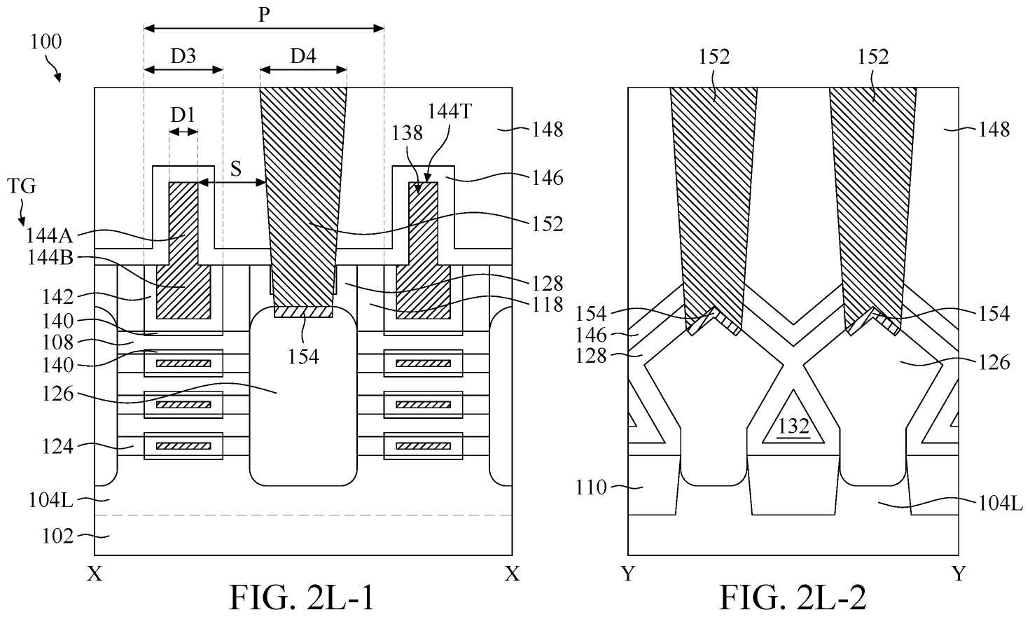

FIGS. 2A-1 through 2L-2 are cross-sectional views illustrating the formation of a semiconductor structure 100 at various intermediate stages, in which FIGS. 2A-1, 2B-1, 2C-1, 2D-1, 2E-1, 2F-1, 2G-1, 2H-1, 2I-1, 2J-1, 2K-1 and 2L-1 correspond to cross-section X-X shown in FIG. 1, and FIGS. 2A-2, 2B-2, 2C-2, 2D-2, 2E-2, 2F-2, 2G-2, 2H-2, 2I-2, 2J-2, 2K-2 and 2L-2 correspond to cross-section Y-Y shown in FIG. 1, in accordance with some embodiments of the disclosure.

FIGS. 2A-1 and 2A-2 illustrate a semiconductor structure 100 after the formation of active regions 104, an isolation structure 110, dummy gate structures 112 and gate spacer layers 118, in accordance with some embodiments.

A semiconductor structure 100 including a substrate 102, active regions 104, an isolation structure 110 and dummy gate structures 112 is provided, as shown in FIGS. 2A-1 and 2A-2, in accordance with some embodiments. In some embodiments, the substrate 102 is a silicon substrate. In some embodiments, the substrate 102 includes an elementary semiconductor such as germanium; a compound semiconductor such as gallium nitride (GaN), silicon carbide (SiC), gallium arsenide (GaAs), gallium phosphide (GaP), indium phosphide (InP), indium arsenide (InAs), and/or indium antimonide (InSb); an alloy semiconductor such as SiGe, GaAsP, AlInAs, AlGaAs, GaInAs, GaInP, and/or GaInAsP; or a combination thereof. Furthermore, the substrate 102 may optionally include an epitaxial layer (epi-layer), may be strained for performance enhancement, may include a silicon-on-insulator (SOI) structure, and/or have other suitable enhancement features.

In some embodiments, the active regions 104 extend in the X direction. The active regions 104 have longitudinal axes parallel to the X direction, in accordance with some embodiments. That is, the dimensions (lengths) of the active regions 104 in the X direction are greater than the dimensions (widths) of the active regions 104 in the Y direction.

The formation of the active regions 104 includes forming an epitaxial stack over the substrate 102 using an epitaxial growth process, in accordance with some embodiments. The epitaxial stack includes alternating first semiconductor layers 106 and second semiconductor layers 108, in accordance with some embodiments. The epitaxial growth process may be molecular beam epitaxy (MBE), metal organic chemical vapor deposition (MOCVD), or vapor phase epitaxy (VPE), or another suitable technique.

In some embodiments, the first semiconductor layers 106 are made of a first semiconductor material and the second semiconductor layers 108 are made of a second semiconductor material with a different composition than the first semiconductor material. The first semiconductor material for the first semiconductor layers 106 has a different lattice constant than the second semiconductor material for the second semiconductor layers 108, in accordance with some embodiments. In some embodiments, the first semiconductor material and the second semiconductor material have different oxidation rates and/or etching selectivity. In some embodiments, the first semiconductor layers 106 are made of SiGe, where the percentage of germanium (Ge) in the SiGe is in a range from about 20 atomic % to about 50 atomic %, and the second semiconductor layers 108 are made of pure or substantially pure silicon. In some embodiments, the first semiconductor layers 106 are Si₁₋ₓGeₓ, where x is more than about 0.3, or Ge (x=1.0) and the second semiconductor layers 108 are Si or Si_{1-y}Ge_{y}, where y is less than about 0.4, and x>y.

The first semiconductor layers 106 are configured as sacrificial layers and will be removed to form gaps to accommodate gate materials, in accordance with some embodiments. The second semiconductor layers 108 will form nanostructures (e.g., nanowires or nanosheets) that laterally extend between source/drain features and serve as the channel for the resulting semiconductor device (such as a nanostructure transistor), in accordance with some embodiments. As the term is used herein, “nanostructures” refers to semiconductor layers that have cylindrical shape, bar shaped and/or sheet shape. Gate stack (not shown) will be formed across and wrap around the nanostructures, in accordance with some embodiments. Although three first semiconductor layers 106 and three second semiconductor layers 108 are shown in FIGS. 2A-1 and 2A-2, the number is not limited to three, and can be two or four, and is less than ten.

In some embodiments, the thickness of each of the first semiconductor layers 106 is in a range from about 3 nm to about 20 nm, such as about 4 nm to about 12 nm. In some embodiments, the thickness of each of the second semiconductor layers 108 is in a range from about 3 nm to about 20 nm, such as about 4 nm to about 12 nm. The thickness of the second semiconductor layers 108 may be greater than, equal to, or less than the first semiconductor layers 106, which may depend on the amount of the gate materials to be filled in spaces where the first semiconductor layers 106 are removed.

The formation of the active regions 104 further includes patterning the epitaxial stack and the underlying substrate 102 using photolithography and etching processes, thereby forming trenches and the active regions 104 protruding from between trenches, in accordance with some embodiments. The portion of the substrate 102 protruding from between the trenches serves as lower fin elements 104L of the active regions 104, in accordance with some embodiments. The remainder of the epitaxial stack (including the first semiconductor layers 106 and the second semiconductor layers 108) serves as the upper fin elements of the active regions 104, in accordance with some embodiments. In some embodiments, the active regions 104 are the fin structures 104, as shown in FIG. 1.

An isolation structure 110 is formed to surround the lower fin elements 104L of the active regions 104, as shown in FIG. 2A-2, in accordance with some embodiments. The bottom surface of the isolation structure 110 is illustrated as a dashed line in FIG. 2A-1. The isolation structure 110 is configured to electrically isolate active regions 104 of the semiconductor structure 100 and is also referred to as a shallow trench isolation (STI) feature, in accordance with some embodiments.

The formation of the isolation structure 110 includes forming an insulating material to overfill the trenches, in accordance with some embodiments. In some embodiments, the insulating material is made of silicon oxide (SiO₂), silicon nitride (SiN), silicon oxynitride (SiON), silicon carbide (SiC), oxygen-doped silicon carbide (SiC:O), oxygen-doped silicon carbonitride (Si(O)CN), or a combination thereof. In some embodiments, the insulating material is deposited using CVD (such as flowable CVD (FCVD), low-pressure CVD (LPCVD), plasma-enhanced CVD (PECVD), high density plasma CVD (HDP-CVD), or high aspect ratio process (HARP)), atomic layer deposition (ALD), another suitable technique, or a combination thereof.

A planarization process is performed on the insulating material to remove a portion of the insulating material above the active regions 104, in accordance with some embodiments. The planarization may be chemical mechanical polishing (CMP), etching back process, or a combination thereof. The insulating material is then recessed by an etching process (such as dry plasma etching and/or wet chemical etching) until the sidewalls of the upper fin elements of the active regions 104 are exposed, in accordance with some embodiments. The remaining insulating material serves as the isolation structure 110, in accordance with some embodiments.

Dummy gate structures 112 are formed across the active regions 104 and the isolation structure 110, as shown in FIG. 2A-1, in accordance with some embodiments. The dummy gate structures 112 are configured as sacrificial structures and will be replaced with the final gate stacks, in accordance with some embodiments. In some embodiments, the dummy gate structures 112 extend in the Y direction. That is, the dummy gate structures 112 have longitudinal axes parallel to the Y direction, in accordance with some embodiments. That is, the dimensions of the dummy gate structures 112 in the Y direction are greater than the dimensions of the dummy gate structures 112 in the X direction. The dummy gate structures 112 surround the channel regions of the active regions 104, in accordance with some embodiments. The dummy gate structures 112 may be the gate structures 112 shown in FIG. 1.

Each of the dummy gate structures 112 includes a dummy gate dielectric layer 114 and a dummy gate electrode layer 116 formed over the dummy gate dielectric layer 114, as shown in FIG. 2A-1, in accordance with some embodiments. In some embodiments, the dummy gate dielectric layer 114 is conformally formed along the upper fin elements of the active regions 104. In some embodiments, the dummy gate dielectric layer 114 is made of one or more dielectric materials, such as silicon oxide (SiO), silicon nitride (SiN), silicon oxynitride (SiON), HfO₂, HfZrO, HfSiO, HfTiO, and/or HfAlO. In some embodiments, the dielectric material is deposited using ALD, CVD, thermal oxidation, physical vapor deposition (PVD), another suitable technique, or a combination thereof.

In some embodiments, the dummy gate electrode layer 116 is made of semiconductor materials such as polysilicon or poly-silicon germanium. In some embodiments, the material for the dummy gate electrode layer 116 is deposited using CVD, ALD, another suitable technique, or a combination thereof. In some embodiments, the formation of the dummy gate structures 112 includes globally and conformally depositing a dielectric material for the dummy gate dielectric layer 114 over the semiconductor structure 100, depositing a material for the dummy gate electrode layer 116 over the dielectric material, planarizing the material for the dummy gate electrode layer 116, and patterning the material for the dummy gate electrode layer 116 and the dielectric material into the dummy gate structures 112.

The patterning process includes forming a patterned hard mask layer (not shown) over the material for the dummy gate electrode layer 116, in accordance with some embodiments. The patterned hard mask layer corresponds to and overlaps the channel regions of the active regions 104, in accordance with some embodiments. The materials for the dummy gate dielectric layer 114 and the dummy gate electrode layer 116, uncovered by the patterned hard mask layer, are etched away until the active regions 104 and the top surface of the isolation structure 110 are exposed, in accordance with some embodiments.

Gate spacer layers 118 are formed over the semiconductor structure 100, as shown in FIGS. 2A-1 and 2A-2, in accordance with some embodiments. The gate spacer layers 118 extend along, and cover, the opposite sides of the dummy gate structures 112, in accordance with some embodiments. In some embodiments, the gate spacer layers 118 extend in the Y direction. The gate spacer layers 118 are used to offset the subsequently formed source/drain features and separate the source/drain features from the gate structure, in accordance with some embodiments. The gate spacer layers 118 may be also referred to as top spacer layers.

In some embodiments, the gate spacer layers 118 are made of a dielectric material, such as silicon oxide (SiO₂), silicon nitride (SiN), silicon oxynitride (SiON), silicon carbide (SiC), oxygen-doped silicon carbide (SiC:O), oxygen-doped silicon carbonitride (Si(O)CN), or a combination thereof, or a combination thereof. In some embodiments, the gate spacer layers 118 are made of low-k dielectric materials with the dielectric constant (k) lower than 10. For example, the dielectric constant value of the gate spacer layers 118 may be lower than a k-value of silicon oxide (SiO), such as lower than 4.2, equal to or lower than about 3.9, such as in a range from about 3.5 to about 3.9.

In some embodiments, the formation of the gate spacer layers 118 includes conformally depositing dielectric materials for the gate spacer layers 118 over the semiconductor structure 100 followed by an anisotropic etching process (such as dry plasma etching). In some embodiments, the deposition process includes ALD, CVD (such as PECVD, LPCVD or HARP), another suitable technique, or a combination thereof. Vertical portions of the dielectric material left on the sidewalls of the dummy gate structures 112 serve as the gate spacer layers 118, in accordance with some embodiments.

FIGS. 2B-1 and 2B-2 illustrate a semiconductor structure 100 after the formation of source/drain recesses 120 and notches 122, in accordance with some embodiments.

An etching process is performed to recess the source/drain regions of the active regions 104, thereby forming source/drain recesses 120, as shown in FIGS. 2B-1 and 2B-2, in accordance with some embodiments. The source/drain recesses 120 extend into the lower fin elements 104L, in accordance with some embodiments.

The gate spacer layers 118 and the dummy gate structures 112 may serve as etch masks such that the source/drain recesses 120 are formed self-aligned opposite sides of the dummy gate structures 112, in accordance with some embodiments. The etching process may be an anisotropic etching process such as dry plasma etching, an isotropic etching process such as dry chemical etching, remote plasma etching or wet chemical etching, and/or a combination thereof. In some embodiments, etching the space layer 122 and etching the source/drain regions of the active regions 104 are subsequently performed in the same etch tool and with different process parameters.

An etching process is performed to laterally recess, from the source/drain recesses 120 toward the channel regions, the first semiconductor layers 106 of the active regions 104, thereby forming notches 122, as shown in FIG. 2B-1, in accordance with some embodiments. In some embodiments, the etching process is an isotropic etching such as dry chemical etching, remote plasma etching, wet chemical etching, another suitable technique, or a combination thereof. The notches 122 are formed between adjacent second semiconductor layers 108 and between the lowermost second semiconductor layer 108 and the lower fin element 104L, in accordance with some embodiments. In some embodiments, the notches 122 are located directly below the gate spacer layers 118.

FIGS. 2C-1 and 2C-2 illustrate a semiconductor structure 100 after the formation of inner spacer layers 124 and source/drain features 126, in accordance with some embodiments.

Inner spacer layers 124 are formed in the notches 122, as shown in FIG. 2C-1, in accordance with some embodiments. The inner spacer layers 124 are formed to abut the sidewalls of the first semiconductor layers 106, in accordance with some embodiments. In some embodiments, the inner spacer layers 124 are located between adjacent second semiconductor layers 108 and between the lowermost second semiconductor layer 108 and the lower fin element 104L. In some embodiments, the inner spacer layers 124 extend directly below the gate spacer layers 118, in accordance with some embodiments. The inner spacer layers 124 may avoid the source/drain features and the gate stack from being in direct contact and are configured to reduce the parasitic capacitance (e.g., Cgs and Cgd) between the gate stack and the source/drain features, in accordance with some embodiments.

In some embodiments, the inner spacer layers 124 are made of dielectric material silicon oxide (SiO₂), silicon nitride (SiN), silicon carbide (SiC), silicon oxynitride (SiON), silicon carbon nitride (SiCN), silicon oxycarbonitride (SiOCN), and/or oxygen-doped silicon carbonitride (Si(O)CN). In some embodiments, the inner spacer layers 124 are made of low-k dielectric materials with the dielectric constant lower than 10. For example, the dielectric constant value of the inner spacer layers 124 may be lower than a k-value of silicon oxide (SiO), such as lower than 4.2, equal to or lower than about 3.9, such as in a range from about 3.5 to about 3.9.

In some embodiments, the formation of the inner spacer layers 124 includes depositing a dielectric material for the inner spacer layers 124 over the semiconductor structure 100 to overfill the notches 122, and then etching away the portion of the dielectric material outside the notches 122. The portions of the inner spacer layers 124 remaining in the notches 122 serve the inner spacer layers 124, in accordance with some embodiments.

Source/drain features 126 are formed in the source/drain recesses 120 on the lower fin elements 104L using an epitaxial growth process, as shown in FIGS. 2C-1 and 2C-3, in accordance with some embodiments. The epitaxial growth process may be MBE, MOCVD, or VPE, another suitable technique, or a combination thereof. The source/drain features 126 are formed on opposite sides of the dummy gate structures 112, in accordance with some embodiments.

In some embodiments, the source/drain features 126 grow on the semiconductor surfaces provided by the second semiconductor layers 108 and the lower fin elements 104L, and abut the inner spacer layers 124. Although the source/drain features 126 are illustrated as having the facet surfaces, the source/drain features 126 may have curved surfaces in some other embodiments.

In some embodiments, the source/drain features 126 are made of any suitable semiconductor material for n-type semiconductor devices or p-type semiconductor devices. In some embodiments, the source/drain features 126 are doped. The concentration of the dopant in the source/drain features 126 in a range from about 1×10¹⁹ cm⁻³ to about 6×10²¹ cm⁻³. An annealing process may be performed on the semiconductor structure 100 to activate the dopants in the source/drain features 126, in accordance with some embodiments.

In some embodiments wherein the active regions 104 are to be formed as an N-type nanostructure device (such as n-channel GAA FET), the source/drain features 126 are made of semiconductor materials such as SiP, SiAs, SiCP, SiC, Si, GaAs, another suitable semiconductor material, or a combination thereof. In some embodiments, the source/drain features 126 are doped with the n-type dopant during the epitaxial growth process. For example, the n-type dopant may be phosphorous (P) or arsenic (As). For example, the source/drain features 126 may be the epitaxially grown Si doped with phosphorous to form silicon:phosphor (Si:P) source/drain features and/or arsenic to form silicon:arsenic (Si:As) source/drain features.

In some embodiments wherein the active regions 104 are to be formed as a P-type nanostructure device (such as p-channel GAA FET), the source/drain features 126 are made of semiconductor materials such as SiGe, Si, GaAs, another suitable semiconductor material, or a combination thereof. In some embodiments, the source/drain features 126 are doped with the p-type dopant during the epitaxial growth process. For example, the p-type dopant may be boron (B) or BF₂. For example, the source/drain features 126 may be the epitaxially grown SiGe doped with boron (B) to form a silicon germanium:boron (SiGe:B) source/drain feature.

FIGS. 2D-1 and 2D-2 illustrate a semiconductor structure 100 after the formation of a contact etching stop layer (CESL) 128 and an interlayer dielectric layer (ILD) 130, in accordance with some embodiments.

A contact etching stop layer 128 is formed over the semiconductor structure 100 to cover the source/drain features 126, as shown in FIGS. 2D-1 and 2D-2, in accordance with some embodiments. The contact etching stop layer 128 is further formed along, and covers, the sidewalls of the gate spacer layers 118 and the top surface of the isolation structure 110, in accordance with some embodiments.

In some embodiments, the contact etching stop layer 128 is made of dielectric material, such as silicon nitride (SiN), silicon oxynitride (SiON), silicon oxide (SiO₂), silicon oxynitride (SiOC), silicon carbide (SiC), oxygen-doped silicon carbide (SiC:O), oxygen-doped silicon carbonitride (Si(O)CN), or a combination thereof. In some embodiments, the contact etching stop layer 128 are made of low-k dielectric materials with the dielectric constant lower than 10. In some embodiments, a dielectric material for the contact etching stop layer 128 is globally and conformally deposited over the semiconductor structure 100 using CVD (such as LPCVD, PECVD, HDP-CVD, or HARP), ALD, another suitable method, or a combination thereof.

Afterward, an interlayer dielectric layer 130 is formed over the contact etching stop layer 128, as shown in FIGS. 2D-1 and 2D-2, in accordance with some embodiments. The interlayer dielectric layer 130 overfills the space between the dummy gate structures 112, in accordance with some embodiments. In some embodiments, the interlayer dielectric layer 130 is made of dielectric material, such as un-doped silicate glass (USG), doped silicon oxide such as borophosphosilicate glass (BPSG), fluoride-doped silicate glass (FSG), phosphosilicate glass (PSG), borosilicate glass (BSG), and/or another suitable dielectric material. In some embodiments, the contact etching stop layer 128 is made of low-k dielectric materials with the dielectric constant lower than 10 such as lower than 4.2.

In some embodiments, the interlayer dielectric layer 130 and the contact etching stop layer 128 are made of different materials and have a great difference in etching selectivity. For example, the contact etching stop layer 128 is a silicon nitride layer, and the interlayer dielectric layer 130 is a silicon oxide layer. In some embodiments, the dielectric material for the interlayer dielectric layer 130 is deposited using such as CVD (such as HDP-CVD, PECVD, HARP or FCVD), another suitable technique, or a combination thereof. The dielectric materials for the contact etching stop layer 128 and the interlayer dielectric layer 130 above the top surface of the dummy gate electrode layer 116 are removed using such as CMP, in accordance with some embodiments. In some embodiments, a space between neighboring source/drain features 126 may be sealed by the contact etching stop layer 128, and referred to as a void 132.

FIGS. 2E-1 and 2E-2 illustrate a semiconductor structure 100 after the formation of gate trenches 134 and gaps 136, in accordance with some embodiments.

The dummy gate structures 112 are removed using an etching process to form gate trenches 134 between the gate spacer layers 118, as shown in FIG. 2E-1, in accordance with some embodiments. In some embodiments, the gate trenches 134 expose the channel regions of the active regions 104. In some embodiments, the gate trenches 134 further expose the sidewalls of the gate spacer layers 118 facing the channel region. In some embodiments, the etching process includes one or more etching processes. For example, when the dummy gate electrode layer 116 is made of polysilicon, a wet etchant such as a tetramethylammonium hydroxide (TMAH) solution may be used to selectively remove the dummy gate electrode layer 116. For example, the dummy gate dielectric layer 114 may be thereafter removed using a plasma dry etching, a dry chemical etching, and/or a wet etching.

Afterward, an etching process is performed on the first semiconductor layers 106 of the active regions 104 to form gaps 136, as shown in FIG. 2E-1, in accordance with some embodiments. The inner spacer layers 124 may be used as an etching stop layer in the etching process, which may protect the source/drain features 126 from being damaged. In some embodiments, the etching process includes a selective wet etching process, such as APM (e.g., ammonia hydroxide-hydrogen peroxide-water mixture) etching process. In some embodiments, the wet etching process uses etchants such as ammonium hydroxide (NH₄OH), TMAH, ethylenediamine pyrocatechol (EDP), and/or potassium hydroxide (KOH) solutions.

The gaps 136 are formed between adjacent second semiconductor layers 108 and between the lowermost second semiconductor layer 108 and the lower fin element 104L, in accordance with some embodiments. In some embodiments, the gaps 136 also expose the sidewalls of the inner spacer layers 124 facing the channel region.

After the one or more etching processes, the four main surfaces of the second semiconductor layers 108 are exposed, in accordance with some embodiments. The exposed second semiconductor layers 108 form nanostructures, in accordance with some embodiments. The nanostructures 108 are vertically stacked and spaced apart from one other, in accordance with some embodiments. As the term is used herein, “nanostructures” refers to the semiconductor layers with cylindrical shape, bar shaped and/or sheet shape. The nanostructures 108 function as channels of the resulting semiconductor devices (e.g., nanostructure transistors such as GAA transistors), in accordance with some embodiments.

FIGS. 2F-1 and 2F-2 illustrate a semiconductor structure 100 after the formation of final gate stacks 138, in accordance with some embodiments.

Final gate stacks 138 are formed in the gate trenches 134 and gaps 136. They are thereby wrapping around the nanostructures 108, as shown in FIG. 2F-1, in accordance with some embodiments. In some embodiments, the final gate stacks 138 extend in the Y direction. The final gate stacks 138 have longitudinal axes parallel to the Y direction, in accordance with some embodiments. That is, the dimensions of the final gate stacks 138 in the Y direction are greater than the dimensions of the final gate stacks 138 in the X direction. In some embodiments, each of the final gate stacks 138 includes an interfacial layer 140, a gate dielectric layer 142 and a metal gate electrode layer 144, as shown in FIG. 2F-1, in accordance with some embodiments.

The interfacial layer 140 is formed on the exposed surfaces of the nanostructures 108 and the exposed top surfaces of the lower fin elements 104L, in accordance with some embodiments. The interfacial layer 140 wraps around the nanostructures 108, in accordance with some embodiments. In some embodiments, the interfacial layer 140 is made of a chemically formed silicon oxide. In some embodiments, the interfacial layer 140 is nitrogen-doped silicon oxide. In some embodiments, the interfacial layer 140 is formed using one or more cleaning processes such as including ozone (O₃), ammonia hydroxide-hydrogen peroxide-water mixture, and/or hydrochloric acid-hydrogen peroxide-water mixture. Semiconductor material from the nanostructures 108 and the lower fin elements 104L is oxidized to form the interfacial layer 140, in accordance with some embodiments.

The gate dielectric layer 142 is formed conformally along the interfacial layer 140 to wrap around the nanostructures 108, in accordance with some embodiments. The gate dielectric layer 142 is also conformally formed along the sidewalls of the gate spacer layers 118 facing the channel region, in accordance with some embodiments. The gate dielectric layer 142 is also conformally formed along the sidewalls of the inner spacer layers 124 facing the channel region, in accordance with some embodiments.

The gate dielectric layer 142 may be high-k dielectric layer. In some embodiments, the high-k dielectric layer is dielectric material with high dielectric constant (k value), for example, greater than 9, such as greater than 20, such as greater than 30. In some embodiments, the high-k dielectric layer includes hafnium oxide (HfO₂), TiO₂, HfZrO, Ta₂O₃, HfSiO₄, ZrO₂, ZrSiO₂, LaO, Al₂O₃, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba, Sr)TiO₃ (BST), a combination thereof, or another suitable material. The high-k dielectric layer may be deposited using ALD, PVD, CVD, and/or another suitable technique.

The metal gate electrode layer 144 is formed to overfill remainders of the gate trenches 134 and gaps 136, in accordance with some embodiments. In some embodiments, the metal gate electrode layer 144 is made of more than one conductive material, such as a metal, metal alloy, conductive metal oxide and/or metal nitride, another suitable conductive material, and/or a combination thereof. For example, the metal gate electrode layer 144 may be made of Ti, Ag, Al, TiAlN, TaC, TaCN, TaSiN, Mn, Zr, TiN, TaN, Ru, Mo, WN, Cu, W, Re, Ir, Co, Ni, another suitable conductive material, or multilayers thereof.

The metal gate electrode layer 144 may be a multi-layer structure with various combinations of a diffusion barrier layer, work function layers with a selected work function to enhance the device performance (e.g., threshold voltage) for n-channel FETs or p-channel FETs, a capping layer to prevent oxidation of work function layers, a glue layer to adhere work function layers to a next layer, and a metal filling layer to reduce the total resistance of the gate stacks, and/or another suitable layer. The metal gate electrode layer 144 may be formed using ALD, PVD, CVD, e-beam evaporation, or another suitable technique.

The portion of the metal gate electrode layer 144 which is formed between the gate spacer layers 118 is referred to as top gate electrode layers TG, in accordance with some embodiments. The top gate electrode layer TG is located above the topmost nanostructures 108, in accordance with some embodiments. The portion of the metal gate electrode layer 144 which is formed between the inner spacer layers 124 is referred to as inner gate electrode layer IG, in accordance with some embodiments. The inner gate electrode layers IG is located between the nanostructures 108 and between the bottommost nanostructures 108 and the lower fin element 104L, in accordance with some embodiments.

A planarization process such as CMP may be performed on the semiconductor structure 100 to remove the materials of the gate dielectric layer 142 and the metal gate electrode layer 144 formed above the top surface of the interlayer dielectric layer 130, in accordance with some embodiments.

The final gate stacks 138 engage the channel region so that current can flow between the source/drain features 126 during operation. The final gate stacks 138 that are wrapped around the nanostructures 108 combine with the neighboring source/drain features 126 to form nanostructure transistors, e.g., n-channel nanostructure transistors and/or p-channel nanostructure transistors.

FIGS. 2G-1 and 2G-2 illustrate a semiconductor structure 100 after an etching process, in accordance with some embodiments.

An etching process is performed on the semiconductor structure 100 to recess the gate spacer layers 118 and the vertical portions of the contact etching stop layer 128 formed along the gate spacer layers 118, thereby exposing the gate dielectric layer 142, as shown in FIG. 2G-1, in accordance with some embodiments. In some embodiments, the etching process may be an anisotropic etching process such as dry plasma etching, an isotropic etching process such as dry chemical etching, remote plasma etching or wet chemical etching, and/or a combination thereof. In some embodiments, the etching process is performed without an additional patterned mask.

After the etching process, the top surfaces 118T of the gate spacer layers 118 are substantially leveled with the top surface 128T of the contact etching stop layer 128, in accordance with some embodiments, as shown in FIG. 2G-1. In alternative embodiments, the top surfaces 118T is higher than the top surface 128T. In alternative embodiments, the top surface 128T is higher than the top surface 118T.

In the etching process, the interlayer dielectric layer 130 is partially recessed, in accordance with some embodiments. After the etching process, the interlayer dielectric layer 130 protrudes from the vertical portions of recessed contact etching stop layer 128, in accordance with some embodiments. After the etching process, the top surface 130T of the interlayer dielectric layer 130 is located at a higher position than the top surfaces 118T of the gate spacer layers 118 and the top surface 128T of the contact etching stop layer 128, in accordance with some embodiments.

In the etching process, the gate dielectric layer 142 and the metal gate electrode layer 144 is substantially unrecessed or slightly recessed, in accordance with some embodiments. After the etching process, the top surface 142T of the gate dielectric layer 142 and the top surface 144T of the metal gate electrode layer 144 are located at a higher position than the top surfaces 118T of the gate spacer layers 118 and the top surface 128T of the contact etching stop layer 128, in accordance with some embodiments.

FIGS. 2H-1 and 2H-2 illustrate a semiconductor structure 100 after an etching process, in accordance with some embodiments.

An etching process is performed on the semiconductor structure 100 to etch the vertical portions of the gate dielectric layer 142 along the sidewalls 144S of the top gate electrode layers TG, as shown in FIG. 2H-1, in accordance with some embodiments. The upper portion of the sidewalls 144S of the top gate electrode layers TG is exposed, in accordance with some embodiments. In some embodiments, the etching process may be an anisotropic etching process such as dry plasma etching, an isotropic etching process such as dry chemical etching, remote plasma etching or wet chemical etching, and/or a combination thereof. In some embodiments, the etching process is performed without an additional patterned mask.

Since the thickness of the gate dielectric layer 142 is thin (e.g., about 1-2 nm), in the case of not recessing the gate spacer layer 118 and the contact etching stop layer 128, the process difficulty of etching the dielectric layer (e.g., only by vertically etching) is high. Therefore, by recessing the gate spacer layers 118 and the contact etching stop layer 128, the gate dielectric layer 142 may be etched vertically and laterally, thereby reducing the process difficulty of recessing the gate dielectric layer 142.

After the etching process, the top surface 142T′ of the gate dielectric layer 142 is substantially leveled with the top surfaces 118T of the gate spacer layers 118 and the top surface 128T of the contact etching stop layer 128, in accordance with some embodiments. In alternative embodiments, the top surface 142T′ is higher than the top surfaces 118T and 128T. In alternative embodiments, the top surfaces 118T and 128T are higher than the top surface 142T′.

After the etching process, the top surface 144T of the metal gate electrode layer 144 is located at a higher position than the top surface 142T′ of the gate dielectric layer 142, in accordance with some embodiments. In some embodiments, the top gate electrode layer TG includes first (or upper) portions 144A protruding from the gate dielectric layer 142 and second (or lower) portions nested within the gate dielectric layer 142, as shown in FIG. 2H-1.

In some embodiments, the top gate electrode layers TG have a height H1 (in the Z direction), the first portions 144A of the top gate electrode layers TG have a height H2 (in the Z direction), and the second portions 144B of the top gate electrode layers TG have a height H3 (in the Z direction). In some embodiments, the ratio of the height H2 to the height H1 is in a range from about 0.05 to about 0.95, for example, in a range from about 0.55 to about 0.8. In some embodiments, the ratio of the height H3 to the height H1 is in a range from about 0.05 to about 0.95, for example, in a range from about 0.2 to about 0.45. In some embodiments, the height H2 is greater than the height H3, as shown in FIG. 2H-1. In alternative embodiments, the height H2 is less than the height H3.

In some embodiments, the portion of the recessed gate dielectric layer 142 above the topmost nanostructure 108 has a height H4 that is greater than 1 nm. After the etching process, the horizontal portion of the gate dielectric layer 142 remains covering the top surface of the topmost nanostructure 108, thereby preventing the topmost nanostructure 108 from being oxidized, in accordance with some embodiments. In addition, the horizontal portion of the contact etching stop layer 128 remains covering the source/drain features 126, thereby preventing the source/drain features 126 from being damaged, in accordance with some embodiments. Therefore, the performance and the manufacturing yield of the resulting semiconductor device may not negatively affected by the etching processes for the contact etching stop layer 128, the gate spacer layers 118 and the gate dielectric layer 142.

During the etching process, the first portions 144A of the top gate electrode layers TG are also laterally recessed, as shown in FIG. 2H-1. in accordance with some embodiments. In some embodiments, the first portions 144A of the top gate electrode layers TG have a dimension D1 in the X direction, and the second portions 144B of the top gate electrode layers TG have a dimension D2 in the X direction. In some embodiments, the dimension D1 is less than the dimension D2. In some embodiments, the ratio of the dimension D1 to the dimension D2 is in a range from about 0.1 to about 0.9, for example, in a range from about 0.3 to about 0.7. In some embodiments, the upper portion of the sidewalls 144S of the top gate electrode layers TG are indented from the lower portion of the sidewalls 144S of the top gate electrode layers TG by a distance D.

During the etching process, the interlayer dielectric layer 130 is entirely removed, so that the sidewalls 128S1 of the vertical portions of the contact etching stop layer 128 along the gate spacer layers 118 and the outer surface 128S2 of the horizontal portion of the contact etching stop layer 128 along the source/drain features 126 are exposed, as shown in FIGS. 2H-1 and 2H-2, in accordance with some embodiments.

FIGS. 2I-1 and 2I-2 illustrate a semiconductor structure 100 after the formation of a lining layer 146, in accordance with some embodiments.

A lining layer 146 is formed over the semiconductor structure 100, as shown in FIGS. 2I-1 and 2I-2, in accordance with some embodiments. The lining layer 146 extends along, and covers, the top surfaces 128T and sidewalls 128S1 of the vertical portions of the contact etching stop layer 128 and the outer surface 128S2 of the horizontal portion of the contact etching stop layer 128, in accordance with some embodiments. The lining layer 146 further extends along, and covers, the top surfaces 118T and the gate spacer layers 118, and the top surface 142T′ of the gate dielectric layer 142, in accordance with some embodiments. The lining layer 146 further extends along, and covers, the top surfaces 144T and the upper portion of the sidewalls 144S of the top gate electrode layers TG, in accordance with some embodiments.

The first portion 144A of the top gate electrode layers TG is surrounded by and in direct contact with the lining layer 146, and the second portion 144B of the top gate electrode layers TG is surrounded by and in direct contact with the gate dielectric layer 142, in accordance with some embodiments.

In some embodiments, the lining layer 146 is made of dielectric material, such as silicon nitride (SiN), silicon oxide (SiO₂), silicon oxynitride (SiOC), silicon carbide (SiC), oxygen-doped silicon carbide (SiC:O), oxygen-doped silicon carbonitride (Si(O)CN), or a combination thereof. In some embodiments, the lining layer 146 are made of low-k dielectric materials with the dielectric constant lower than 20, e.g., lower than 10. In some embodiments, a dielectric material for the lining layer 146 is globally and conformally deposited over the semiconductor structure 100 using CVD (such as LPCVD, PECVD, HDP-CVD, or HARP), ALD, another suitable method, or a combination thereof.

FIGS. 2J-1 and 2J-2 illustrate a semiconductor structure 100 after the formation of a filling layer 148, in accordance with some embodiments.

A filling layer 148 is formed over the lining layer 146, as shown in FIGS. 2J-1 and 2J-2, in accordance with some embodiments. The filling layer 148 overfills the space between the top gate electrode layers TG, in accordance with some embodiments. In some embodiments, the filling layer 148 is made of dielectric material such as silicon oxide (SiO₂), silicon oxynitride (SiON), silicon nitride (SiN), silicon carbide (SiC), oxygen-doped silicon carbide (SiC:O), oxygen-doped silicon carbonitride (Si(O)CN), or a combination thereof. In some embodiments, the filling layer 148 is made of low-k dielectric materials with the dielectric constant lower than 10. In some embodiments, the k-value of the filling layer 148 may be lower than a k-value of silicon oxide (SiO), such as lower than 4.2, equal to or lower than about 3.9, such as in a range from about 3.5 to about 3.9.

In some embodiments, the filling layer 148 and the lining layer 146 are made of different materials and have a great difference in etching selectivity. In some embodiments, the dielectric constant of the filling layer 148 is lower than the dielectric constant of the lining layer 146. In an embodiment where the lining layer 146 is a silicon nitride layer and the filling layer 148 is a silicon oxide layer, the lining layer 146 may prevent the first portion 144A of the top gate electrode layers TG from being oxidized, thereby reducing the risk of negatively affecting threshold voltage of the resulting semiconductor device.

In some embodiments, the filling layer 148 is deposited using such as CVD (such as HDP-CVD, PECVD, HARP or FCVD), another suitable technique, or a combination thereof. The filling layer 148 is then planarized such as using CMP or an etching-back process, in accordance with some embodiments.

FIGS. 2K-1 and 2K-2 illustrate a semiconductor structure 100 after the formation of contact openings 150, in accordance with some embodiments.

A patterning process is performed on the semiconductor structure 100 to form contact openings 150, as shown in FIGS. 2K-1 and 2K-2, in accordance with some embodiments. The patterning process includes depositing a hard mask layer (not shown) over the filling layer 148, and forming a patterned photoresist layer (not shown) on the hard mask layer using a photolithography process, in accordance with some embodiments. The mask layer is made of metal oxide (e.g., AlO, TiO, LaO, HfO, etc.), a nitrogen-free anti-reflection layer (NFARL), carbon-doped silicon dioxide (e.g., SiO₂:C), titanium nitride (TiN), boron nitride (BN), a multilayer thereof, another suitable material, and/or a combination thereof.

The patterning process further includes etching the hard mask layer to transfer the opening pattern of the patterned photoresist layer into the mask layer, and then etching the filling layer 148, the lining layer 146 and the contact etching stop layer 128 using the patterned hard layer to form contact openings 150, in accordance with some embodiments. The etching process may be an anisotropic etching process such as dry plasma etching. The etching process is performed until the source/drain features 126 are exposed from the contact openings 150, in accordance with some embodiments.

FIGS. 2L-1 and 2L-2 illustrate a semiconductor structure 100 after the formation of contact plugs 152, in accordance with some embodiments.

Contact plugs 152 are formed in the contact openings 150 and land on the source/drain features 126, as shown in FIGS. 2K-1 and 2K-2, in accordance with some embodiments. The contact plugs 152 are electrically connected to the source/drain features 126, in accordance with some embodiments. In some embodiments, the formation of the contact plugs 152 includes forming silicide layers 154 (such as WSi, NiSi, TiSi and/or CoSi) on the exposed surfaces of the source/drain features 126, depositing one or more conductive materials over the silicide layer to fill the contact openings 150, and planarizing the one or more conductive materials until the top surface of the filling layer 148 is exposed using, for example, CMP.

In some embodiments, the conductive material is deposited using CVD, PVD, e-beam evaporation, ALD, electroplating (ECP), electroless deposition (ELD), another suitable method, or a combination thereof. After the planarization process, the top surfaces of the contact plugs 152 and the filling layer 148 are substantially coplanar, in accordance with some embodiments.

The contact plugs 152 may have a multilayer structure including, for example, liner layers, glue layers, barrier layers, seed layers, metal bulk layers, another suitable layer, or a combination thereof. For example, a barrier/adhesive layer (not shown) may optionally be deposited along the sidewalls and the bottom surfaces of the contact openings 150. A metal bulk layer is then deposited on the barrier/adhesive layer (if formed) to fill the remainder of the contact openings 150.

The barrier/adhesive layer is used to prevent the metal from the subsequently formed metal material from diffusing into the dielectric material (e.g., the filling layer 148, the lining layer 146 and the contact etching stop layer 128), and/or to improve adhesion between the subsequently formed metal bulk material and the dielectric materials. The barrier/adhesive layer may be made of tantalum (Ta), tantalum nitride (TaN), titanium (Ti), titanium nitride (TiN), cobalt tungsten (CoW), another suitable material, or a combination thereof. If the subsequently formed metal material does not easily diffuse into the dielectric material, the barrier layer may be omitted.

In some embodiments, the metal bulk layer is formed using a selective deposition technique such as cyclic CVD process or ELD process, and it is not necessary to form an adhesive layer in the contact openings 150 before depositing the metal bulk material. In some embodiments, the metal bulk layer is made of one or more conductive materials with low resistance and good gap-fill ability, for example, cobalt (Co), nickel (Ni), tungsten (W), titanium (Ti), tantalum (Ta), copper (Cu), rhodium (Rh), iridium (Ir), platinum (Pt), aluminum (Al), ruthenium (Ru), molybdenum (Mo), another suitable metal material, or a combination thereof.

As the scale of semiconductor devices continues to shrink, one of the design challenges of semiconductor devices is to scaling down the gate-to-gate pitch P. The scaling of the gate-to-gate pitch P can be achieved by shrinking the critical dimension D3 of the final gate stack 138, the critical dimension D4 of the contact plug 152, and/or the spacing between the final gate stack 138 and the contact plug 152.

The shrinkage of the critical dimension of the gate stack (or the dummy gate structure) may degrade the gate-filling capability of the metal gate electrode layer, thereby negatively affecting the threshold voltage of the resulting semiconductor device. The shrinkage of the critical dimension of the contact plug may reduce the landing area of the contact plug on the source/drain feature, thereby increasing the resistance of the resulting semiconductor device.

Furthermore, the shrinkage of the spacing between the gate stack and the contact plug is limited by the capability of the photolithography process for forming the contact opening 150 (e.g., overlay window). In the instances in which the contact plug is offset toward the final gate stack, the risk of leakage between the top gate electrode layers and the contact plug may significantly increase, because the gate dielectric layer 142 may contain conductive material (e.g., titanium) and may have electrical conductivity to serve as a leakage path. The most prone location for leakage may be on top surface of the top gate electrode layer as this is the closest spacing between the gate stack and the contact plug.

In accordance with some embodiments of the present disclosure, the gate dielectric layer 142 is recessed after the formation of the final gate stack 138 so as to shrink the critical dimension of the top portion of the final gate stack 138 without degrading the gate-filling capability of the metal gate electrode layer, and the spacing S between the contact plug 152 and the top surface 144T of the final gate stack 138 may thus increase. That is, because the gate dielectric layer 142 that may serve as a leakage path is recessed, the isolation window between the contact plug 152 and the final gate stack 138 may increase.

When the contact plug 152 is offset toward the final gate stack 144, the risk of leakage between the top gate electrode layer TG and the contact plug 152 may not significantly increase. Therefore, the overlay window of the photolithography process for forming the contact opening 150 may be relaxed, which may facilitate the scaling down of the gate-to-gate pitch.

In addition, the upper portion 144A of the top gate electrode layer TG is surrounded by the lining layer 146 which has a lower dielectric constant than the gate dielectric layer 142 and a better electrical isolation than the gate dielectric layer 142, in accordance with some embodiments. Therefore, the parasitic capacitance between the top gate electrode layer TG and the contact plug 152 may reduce, thereby improving the performance (e.g., speed) of the resulting semiconductor device, in accordance with some embodiments.

It should be understood that the semiconductor structure 100 may undergo further CMOS processes to form various features over the semiconductor structure, such as a multilayer interconnect structure (e.g., conductive vias, metal lines, inter metal dielectric layers, passivation layers, etc.).

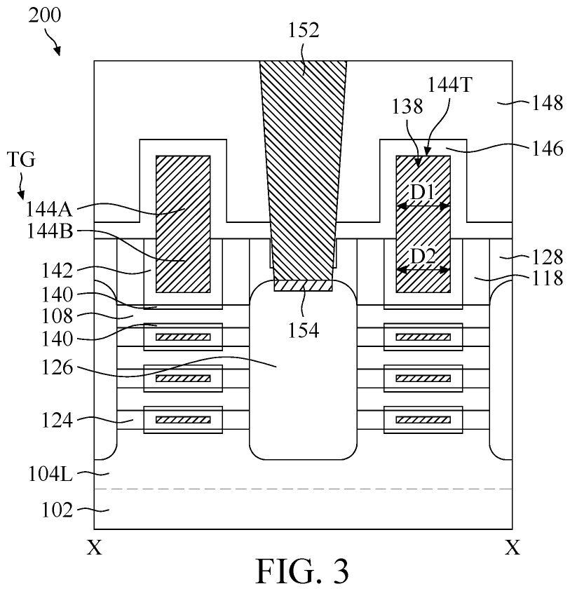

FIG. 3 is a modification of the semiconductor structure 100 of FIG. 2L-1, in accordance with some embodiments of the disclosure. FIG. 3 illustrates a semiconductor structure 200 that is similar to the semiconductor structure 100 of FIG. 2L-1 except that the dimension D1 of the upper portion 144A of the top gate electrode layer TG.

In the etching process of etching the gate dielectric layer 142, the first portions 144A of the top gate electrode layers TG are not laterally recessed, as shown in FIG. 3, in accordance with some embodiments. In some embodiments, the dimension D1 of the first portions 144A of the top gate electrode layers TG in the X direction are substantially the same as the dimension D2 of the second portions 144B of the top gate electrode layers TG in the X direction.

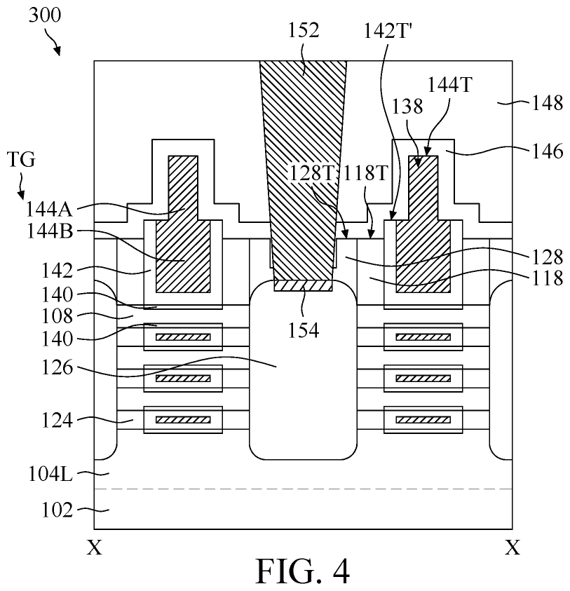

FIG. 4 is a modification of the semiconductor structure 100 of FIG. 2L-1, in accordance with some embodiments of the disclosure. FIG. 4 illustrates a semiconductor structure 300 that is similar to the semiconductor structure 100 of FIG. 2L-1 except that the location of the top surface 142T′ of the gate dielectric layer 142.

Due to the characteristics of the etching process, after the etching process of etching the gate dielectric layer 142, the top surface 142T′ of the gate dielectric layer 142 is located at a higher position than the top surfaces 118T of the gate spacer layers 118 and the top surface 128T of the contact etching stop layer 128, as shown in FIG. 4, in accordance with some embodiments.

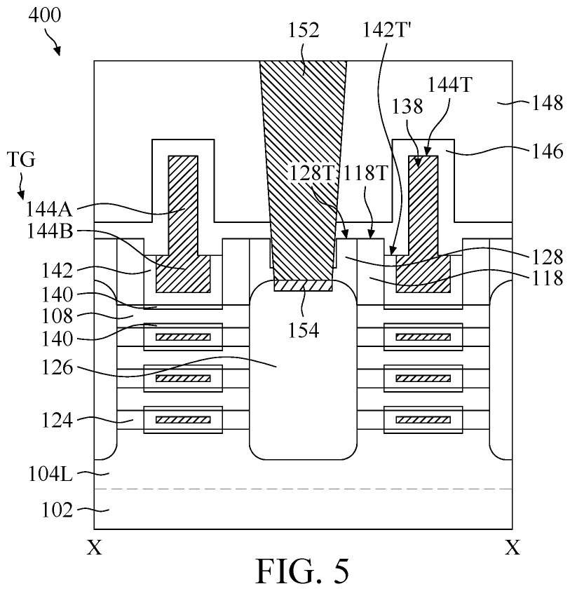

FIG. 5 is a modification of the semiconductor structure 100 of FIG. 2L-1, in accordance with some embodiments of the disclosure. FIG. 5 illustrates a semiconductor structure 400 that is similar to the semiconductor structure 100 of FIG. 2L-1 except that the location of the top surface 142T′ of the gate dielectric layer 142.

Due to the characteristics of the etching process, after the etching process of etching the gate dielectric layer 142, the top surface 142T′ of the gate dielectric layer 142 is located at a lower position than the top surfaces 118T of the gate spacer layers 118 and the top surface 128T of the contact etching stop layer 128, as shown in FIG. 5, in accordance with some embodiments.

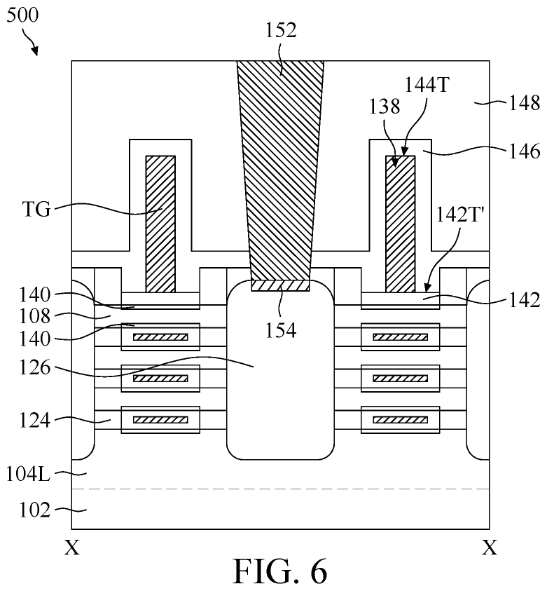

FIG. 6 is a modification of the semiconductor structure 100 of FIG. 2L-1, in accordance with some embodiments of the disclosure. FIG. 6 illustrates a semiconductor structure 500 that is similar to the semiconductor structure 100 of FIG. 2L-1 except that the location of the top surface 142T′ of the gate dielectric layer 142.

In the etching process of etching the gate dielectric layer 142, the vertical portions of the gate dielectric layer 142 along the top gate electrode layers TG are entirely removed, so that the top gate electrode layers TG are entirely exposed, as shown in FIG. 5, in accordance with some embodiments. The top surface 142T′ of the gate dielectric layer 142 is substantially leveled with the bottom surfaces of the top gate electrode layers TG, in accordance with some embodiments.

In some embodiments, the lining layer 146 surrounds and is in direct contact with the entire top gate electrode layers TG. The horizontal portion of the gate dielectric layer 142 remains covering the top surface of the topmost nanostructure 108, thereby preventing the topmost nanostructure 108 from being oxidized, in accordance with some embodiments.

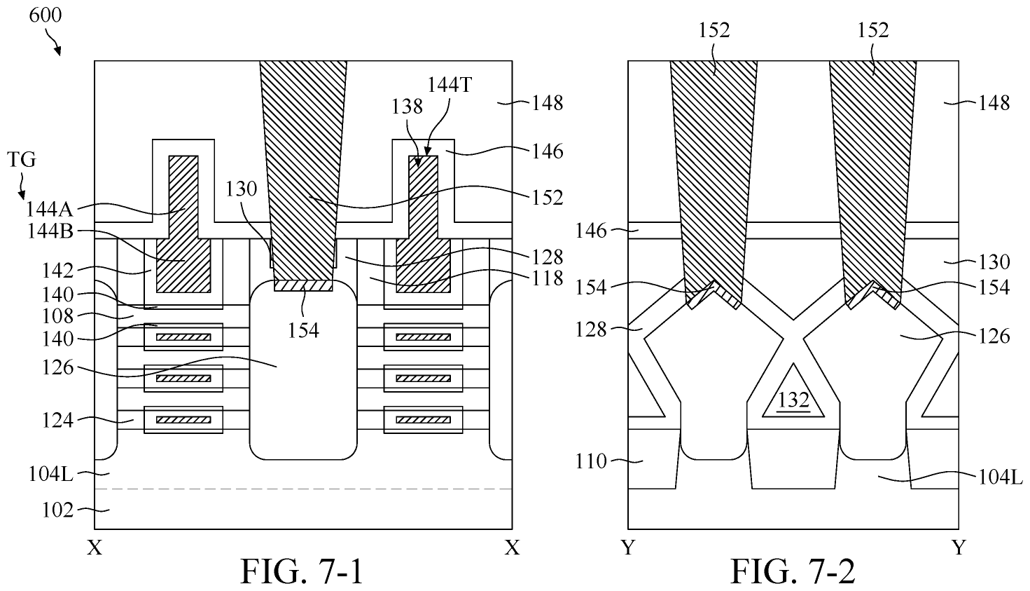

FIGS. 7-1 and 7-2 are a modification of the semiconductor structure 100 of FIGS. 2L-1 and 2L-2, in accordance with some embodiments of the disclosure. FIGS. 7-1 and 7-2 illustrate a semiconductor structure 600 that is similar to the semiconductor structure 100 of FIGS. 2L-1 and 2L-2 except that the interlayer dielectric layer 130 remains.

After the etching process of etching the gate dielectric layer 142, the interlayer dielectric layer 130 remains on the contact etching stop layer 128, as shown in FIGS. 7-1 and 7-2, in accordance with some embodiments. The lining layer 146 extends along, and covers, the top surface of the interlayer dielectric layer 130, in accordance with some embodiments.

As described above, the method for forming the semiconductor structure includes recessing the gate dielectric layer 142 to expose the top gate electrode layer TG. As a result, the critical dimension of the top portion of the final gate stack 138 may shrink, and the spacing S between the contact plug 152 and the final gate stack 138 may thus increase. Therefore, the overlay window of the photolithography process for forming the contact opening 150 may be relaxed, which may facilitate the scaling down of the gate-to-gate pitch.

In addition, the top gate electrode layer TG is at least partially surrounded by the lining layer 146 which has a lower dielectric constant than the gate dielectric layer 142 and a better electrical isolation than the gate dielectric layer 142. Therefore, the parasitic capacitance between the top gate electrode layer TG and the contact plug 152 may reduce, thereby improving the performance of the resulting semiconductor device, in accordance with some embodiments.

Embodiments of a semiconductor structure and the method for forming the same may be provided. The method for forming the semiconductor structure includes recessing the gate dielectric layer to expose the gate electrode layer, forming a filling layer over the gate stack and the source/drain feature, and forming a contact plug through the filling layer and on the source/drain feature. As a result, the critical dimension of the top portion of the gate stack may shrink. Therefore, the overlay window of the photolithography process for forming the contact opening may be relaxed, which may facilitate the scaling down of the gate-to-gate pitch.

In some embodiments, a method for forming a semiconductor structure is provided. The method includes forming a channel layer over a substrate, forming a source/drain feature adjoining the channel layer, and forming a gate stack over the channel layer. The gate stack includes a gate dielectric layer and a gate electrode layer nested within the gate dielectric layer. The method also includes recessing the gate dielectric layer to expose the gate electrode layer, forming a filling layer over the gate stack and the source/drain feature, and forming a contact plug through the filling layer and on the source/drain feature.

In some embodiments, a method for forming a semiconductor structure is provided. The method includes forming an active region over a substrate. The active region includes forming a dummy gate structure over an active region, forming a gate spacer layer alongside the dummy gate structure, removing the dummy gate structure, forming a gate dielectric layer along the gate spacer layer, forming a gate electrode layer over the gate dielectric layer, recessing the gate spacer layer, recessing the gate dielectric layer, and forming a lining layer along a portion of the gate electrode layer protruding from the gate dielectric layer and over the gate spacer layer.

In some embodiments, a semiconductor structure is provided. The semiconductor structure includes a plurality of nanostructures over a substrate, and a gate stack above a topmost one of the nanostructure. The gate stack includes a gate electrode layer and a gate dielectric layer surrounding and in direct contact with a lower portion of the gate electrode layer. The semiconductor structure also includes a lining layer surrounding and in direct contact with an upper portion of the gate electrode layer. A dielectric constant of the lining layer is lower than a dielectric constant of the gate dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor structure, comprising:
forming a channel layer over a substrate;
forming a source/drain feature adjoining the channel layer;
forming a gate stack over the channel layer, wherein the gate stack includes a gate dielectric layer and a gate electrode layer nested within the gate dielectric layer;
recessing the gate dielectric layer to expose the gate electrode layer;
forming a filling layer over the gate stack and the source/drain feature; and
forming a contact plug through the filling layer and on the source/drain feature.

2. The method for forming the semiconductor structure as claimed in claim 1, wherein after recessing the gate dielectric layer, a top surface of the gate dielectric layer is lower than a top surface of the gate electrode layer.

3. The method for forming the semiconductor structure as claimed in claim 1, further comprising, before recessing the gate dielectric layer:
forming a gate spacer layer alongside the gate stack; and
recessing the gate spacer layer to expose the gate dielectric layer.

4. The method for forming the semiconductor structure as claimed in claim 1, further comprising:
forming a lining layer along sidewalls of the gate electrode layer, wherein the filling layer is formed over the lining layer and made of a different material than the lining layer.

5. The method for forming the semiconductor structure as claimed in claim 4, wherein the gate electrode layer includes an upper portion surrounded by and in direct contact with the lining layer and a lower portion surrounded by and in direct contact with the gate dielectric layer.

6. The method for forming the semiconductor structure as claimed in claim 5, wherein the upper portion of the gate electrode layer is narrower than the lower portion of the gate electrode layer.

7. The method for forming the semiconductor structure as claimed in claim 4, wherein a dielectric constant of the lining layer is lower than a dielectric constant of the gate dielectric layer.

8. The method for forming the semiconductor structure as claimed in claim 1, further comprising, before recessing the gate dielectric layer:
forming a contact etching stop layer over the source/drain feature;
forming an interlayer dielectric layer over the contact etching stop layer;
recessing the contact etching stop layer; and
removing the interlayer dielectric layer to expose the contact etching stop layer.

9. The method for forming the semiconductor structure as claimed in claim 8, wherein after recessing the gate dielectric layer, a top surface of the gate dielectric layer is lower than a top surface of the contact etching stop layer.

10. The method for forming the semiconductor structure as claimed in claim 8, wherein the channel layer includes a plurality of nanostructures, and the gate stack includes portions between the nanostructures.

11. A method for forming a semiconductor structure, comprising:
forming a dummy gate structure over an active region;
forming a gate spacer layer alongside the dummy gate structure;
removing the dummy gate structure;
forming a gate dielectric layer along the gate spacer layer;
forming a gate electrode layer over the gate dielectric layer;
recessing the gate spacer layer;
recessing the gate dielectric layer; and
forming a lining layer surrounding a portion of the gate electrode layer protruding from the gate dielectric layer and over the gate spacer layer.

12. The method for forming the semiconductor structure as claimed in claim 11, wherein a dielectric constant of the lining layer is less than 20, and a dielectric constant of the gate dielectric layer is greater than 20.

13. The method for forming the semiconductor structure as claimed in claim 11, further comprising:
recessing the active region to form a recess;
forming a source/drain feature in the recess;
forming an interlayer dielectric layer over the source/drain feature; and
at least partially removing the interlayer dielectric layer while etching the gate dielectric layer.

14. The method for forming the semiconductor structure as claimed in claim 13, wherein the lining layer is formed over the interlayer dielectric layer.

15. The method for forming the semiconductor structure as claimed in claim 11, further comprising:
forming a filling layer over the lining layer, wherein a dielectric constant of the filling layer is less than a dielectric constant of the lining layer.

16. A semiconductor structure, comprising:
a plurality of nanostructures over a substrate;
a gate stack above a topmost one of the nanostructures, wherein the gate stack comprises a gate electrode layer and a gate dielectric layer surrounding and in direct contact with a lower portion of the gate electrode layer; and
a lining layer surrounding and in direct contact with an upper portion of the gate electrode layer, wherein a dielectric constant of the lining layer is lower than a dielectric constant of the gate dielectric layer.

17. The semiconductor structure as claimed in claim 16, further comprising:
a source/drain feature adjoining the plurality of nanostructures; and
a contact etching stop layer over the source/drain feature, wherein the lining layer extends over the contact etching stop layer.

18. The semiconductor structure as claimed in claim 17, further comprising:
a filling layer over the lining layer; and
a contact plug penetrating through the filling layer, the lining layer and the contact etching stop layer and landing on the source/drain feature.

19. The semiconductor structure as claimed in claim 17, wherein a top surface of the gate dielectric layer is lower than a top surface of the contact etching stop layer.

20. The semiconductor structure as claimed in claim 16, wherein the upper portion of the gate electrode layer surrounded by the lining layer is narrower than the lower portion of the gate electrode layer surrounded by the gate dielectric layer.
